(19) United States
(12) Patent Application Publication
(10) Pub. No.: US 2025/0087510 A1
(43) Pub. Date: Mar. 13, 2025

(54) System and Method for Monitoring Moving and Stepping Silicon Wafers

(71) Applicant: TCL ZHONGHUAN RENEWABLE ENERGY TECHNOLOGY CO., LTD., Tianjin (CN)

(72) Inventors: Lihui JIN, Tianjin (CN); Hua YANG, Tianjin (CN); Zhigao REN, Tianjin (CN); Mingqiang GENG, Tianjin (CN); Huan WANG, Tianjin (CN); Chuanling AI, Tianjin (CN); Dawei WANG, Tianjin (CN); Zhijun WU, Tianjin (CN); Hongxia CEN, Tianjin (CN); Chen WEI, Tianjin (CN)

(73) Assignee: TCL ZHONGHUAN RENEWABLE ENERGY TECHNOLOGY CO., LTD., Tianjin (CN)

(21) Appl. No.: 18/554,808

(22) PCT Filed: Jun. 26, 2023
(86) PCT No.: PCT/CN2023/102409

§ 371 Date: Oct. 11, 2023

(30) Foreign Application Priority Data
Jun. 27, 2022 (CN) 202210736305.3

(51) Int. Cl. H01L 21/67; H01L 21/66

(52) U.S. Cl. CPC H01L 21/67259; H01L 21/67288; H01L 22/12; H01L 21/67057

(57) ABSTRACT

Embodiments of the present disclosure are directed to a system for monitoring moving and stepping silicon wafers and a method adopts the system. The system includes a first sensing element to monitor whether a gap between adjacent silicon wafers exists, and a second sensing element to monitor whether two silicon wafers are laminated. The first sensing element and the second sensing element are both disposed in a slot where the silicon wafers are turned over, and suspended on a front side of a sorting wheel in the slot and obliquely arranged towards one side of the sorting wheel. The system installed in the narrow space between the cleaning tank and the sorting tank has simple structure and is capable of quickly and accurately monitoring the silicon wafer turnover, and accurately determining whether there is a continuous or laminated silicon wafer during the silicon wafer turnover process.

### CROSS-REFERENCE TO RELATED APPLICATION

This application claims priority to and the benefit of Chinese Patent Application No. 202210736305.3, filed in the China National Intellectual Property Administration on Jun. 27, 2022, the disclosure of which is hereby incorporated by reference in its entirety.

### FIELD OF THE INVENTION

The present disclosure relates to the field of silicon wafer cleaning, more particularly, to a system for monitoring moving and stepping silicon wafers and a method adopts the monitoring system.

### BACKGROUND

After the silicon wafer is unglued, silicon wafers will first be turned from a vertical state to a horizontal state in the cleaning tank. This process is called silicon wafer sorting, which is an important part of silicon wafer cleaning. During sorting process, partial wafer lamination or complete wafer lamination sometimes happen. Generally, partial wafer lamination is often referred to as two silicon wafers connecting. The complete wafer lamination indicates that two silicon wafers are overlapped and placed up and down, which are often referred to as laminated silicon wafers. These are abnormal phenomena during sorting. Once the partial wafer lamination or the complete wafer lamination occur during sorting, it will directly affect the subsequent silicon wafer cleaning work and also affect the silicon wafer stepping speed. When a silicon wafer is turned over, the space at the connection between the cleaning tank and the sorting tank is limited. How to quickly and accurately identify whether partial wafer lamination or complete wafer lamination occurs in the narrow space during the silicon wafer turning process is one of the key contents to ensure the silicon wafer cleaning quality.

### SUMMARY

The present disclosure is directed to a monitoring system for moving and stepping silicon wafers and a monitoring method adopts the monitoring system, which solves the technical problem of how to quickly and accurately identify whether a silicon wafer is continuous or laminated in a narrow space during the silicon wafer flipping process.

To solve at least one of the above technical problems, an embodiment of the present disclosure is directed to a system for monitoring moving and stepping silicon wafers. The system includes a first sensing element configured to monitor whether a gap between adjacent silicon wafers exists, and a second sensing element configured to monitor whether two silicon wafers are laminated. The first sensing element and the second sensing element are both disposed in a slot where the silicon wafers are turned over, and the first sensing element and the second sensing element are both suspended on a front side of a sorting wheel in the slot and obliquely arranged towards one side of the sorting wheel.

Furthermore, the first sensing element and the second sensing element are both disposed in an end of the slot near the sorting wheel.

Furthermore, the first sensing element and the second sensing element are disposed in a direction and orientated in the same direction across a width of the slot. The first sensing element and the second sensing element are arranged side-by-side at intervals or positioned in offset arrangement along a vertical direction.

Furthermore, the system further includes a mounting plate configured to fix the first sensing element and the second sensing element and a crossbar used for fixing the mounting plate. Two ends of the crossbar are respectively fixed on two side walls of the slot. The mounting plate is arranged along a length direction of the crossbar and located in the middle of the crossbar. The first sensing element and the second sensing element are both configured at an upper section portion of the mounting plate and located above the crossbar.

Furthermore, the mounting plate and the crossbar are detachably connected. The first sensing element, the second sensing element and the mounting plate are detachably connected. A width of the mounting plate is not greater than one fifth of a length of the crossbar.

Furthermore, the system further includes a controller electrically connected to the first sensing element and the second sensing element. The controller is disposed at an outer side of the slot.

Another embodiment of the present disclosure is directed to a method for monitoring moving and stepping silicon wafers performed with a monitoring system. The monitoring system includes a first sensing element configured to monitor whether a gap between adjacent silicon wafers exists, and a second sensing element configured to monitor whether two silicon wafers are laminated. The first sensing element and the second sensing element are both disposed in a slot where the silicon wafers are turned over, and the first sensing element and the second sensing element are both suspended on a front side of a sorting wheel in the slot and obliquely arranged towards one side of the sorting wheel. The method includes: monitoring a starting time of each of the silicon wafers passing through a measured position to obtain a travel time of the silicon wafer during a time period of silicon wafer stepping; measuring a thickness of the silicon wafer at the measured position to obtain a measured thickness of the silicon wafer; determining whether the silicon wafer is an abnormal silicon wafer based on a comparison of the travel time with a standard time and a comparison of the measured thickness of the silicon wafer with a standard thickness of a single silicon wafer.

Furthermore, the method further includes: determining that the silicon wafer is an abnormal silicon wafer when the travel time exceeds the standard time.

Furthermore, the method further includes: determining that the silicon wafer is a normal silicon wafer when the travel time is within the standard time and the measured thickness of the silicon wafer is within the standard thickness of the single silicon wafer; and determining that the silicon wafer is an abnormal silicon wafer when the travel time is within the standard time and the measured thickness of the silicon wafer is not within the standard thickness of the single silicon wafer.

Furthermore, the method further includes: adjusting a step amount of following silicon wafers after the abnormal silicon wafer is determined.

The monitoring system for moving and stepping silicon wafers designed by the present disclosure is installed in the narrow space between the cleaning tank and the sorting tank, has simple structure and is easy to control, is capable of quickly and accurately monitoring the silicon wafer turnover, and accurately determining whether there is a continuous or laminated silicon wafer during the silicon wafer turnover process.

The present disclosure is also directed to the monitoring method for moving and stepping silicon wafers, which adopts the monitoring system. Based on the comparison of the travel time and travel thickness of silicon wafers with the standard time and standard thickness, it can determine whether the silicon wafers are continuous silicon wafers or laminated silicon wafers, so as to find abnormal silicon wafers. The detection process is simple, easy to control, and accurate. It can also automatically adjust the step size of subsequent silicon wafers in the migration process.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a structural diagram of a monitoring system for moving and stepping silicon wafers according to one embodiment of the present disclosure.

FIG. 2 is a layout of a first sensing element and a second sensing element on a mounting plate according to one embodiment of the present disclosure.

FIG. 3 is a side view of the monitoring system according to one embodiment of the present disclosure.

FIG. 4 is a layout of the first sensing element and the second sensing element on the mounting plate according to another embodiment of the present disclosure.

FIG. 5 is a side view of the monitoring system according to another embodiment of the present disclosure.

FIG. 6 is a flowchart of the monitoring method according to one embodiment of the present disclosure.

### DESCRIPTION OF THE EMBODIMENTS

The present disclosure will be described in detail below in conjunction with the accompanying drawings and specific embodiments

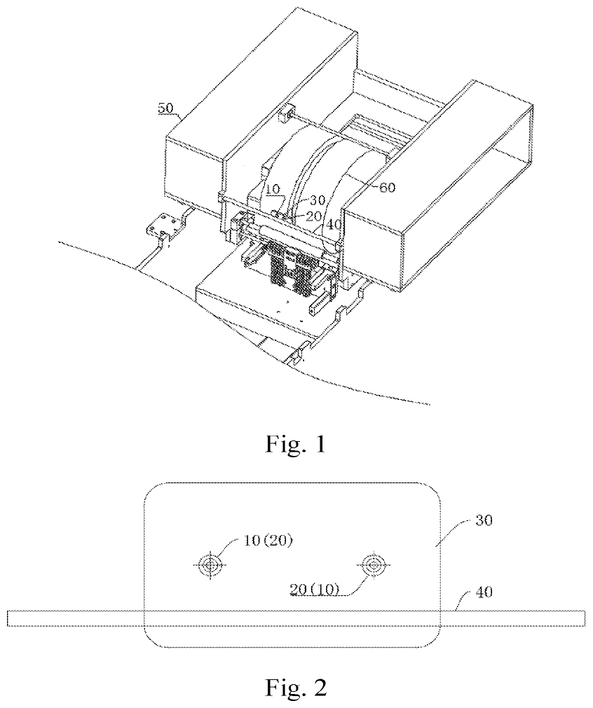

In this embodiment, the present disclosure is directed to a monitoring system for moving and stepping silicon wafers. As shown in FIG. 1. The monitoring system includes a first sensing element 10 for monitoring whether two adjacent silicon wafers have gaps and a second sensing element 20 for monitoring whether silicon wafers are laminated. The first sensing element 10 and the second sensing element 20 are disposed in a slot 50 where the silicon wafers are turned over from a vertical direction to a horizontal direction. The first sensing element 10 and the second sensing element 20 are both suspended on a front side of a sorting wheel 60 in the slot 50 and obliquely arranged towards one side of the sorting wheel 60. In the actual sorting process, both continuous silicon wafers and laminated silicon wafers are abnormal phenomena. Continuous silicon wafers indicates that adjacent silicon wafers are connected and partially overlapped. Laminated silicon wafers indicates that the adjacent silicon wafers are completely stacked. The first sensing element 10 is configured to monitor whether there is gap between adjacent silicon wafers. When adjacent silicon wafers are connected, there is no gap between adjacent silicon wafers, extending a travel time of silicon wafers. The travel time can be monitored based on whether there is gap between adjacent silicon wafers, and then indirectly determine whether adjacent silicon wafers are connected. The second sensing element 20 monitors whether the silicon wafers are laminated. When the silicon wafers are laminated, the average thickness of the monitored silicon wafer will be greater than a thickness of a single silicon wafer. The second sensing element 20 monitors the thickness of the silicon wafer to determine whether the silicon wafers are laminated. The silicon wafer lamination increases the thickness of the measured silicon wafer. The first sensing element 10 can detect whether there is a gap between two adjacent silicon wafers, but it cannot detect whether the two adjacent silicon wafers are laminated. The second sensing element 20 can detect whether the two adjacent silicon wafers are laminated. Furthermore, the first sensing element 10 and the second sensing element 20 are combined to monitor abnormal silicon wafers based on different monitoring principles to find out all silicon wafers with continuous and/or laminated silicon wafers.

The first sensing element 10 and the second sensing element 20 are light sensing elements, both of which are inclined towards the side where the silicon wafer is close to the sorting wheel 60. When the silicon wafer is close to the sorting wheel 60 and reverses step by step, the first sensing element 10 can determine whether the silicon wafers are connected based on the travel time of a single silicon wafer. When the first sensing element 10 monitors that there is a gap between two adjacent silicon wafers, it indicates that the two adjacent silicon wafers are stepping normally and there is no connected phenomenon, and they are fixed at the same end of the slot 50 near the sorting wheel 60. Because of the limited space in the slot 50, they are all set at the same end, which can monitor the silicon wafer synchronously, so that we can know which silicon wafer has a problem. The inclination of the first sensing element 10 and the second sensing element 20 towards the silicon wafer on the sorting wheel 60 is not specifically limited here, as long as the beam emitted by the first sensing element 10 and the second sensing element 20 can vertically shine on the silicon wafer surface, the silicon wafer movement time and silicon wafer thickness can be measured, that is, whether adjacent silicon wafers are connected or whether there is a silicon wafer stacking setting can be monitored. In this embodiment, the thickness of the silicon wafer obtained by the second sensing element 20 refers to its average thickness, and the same applies later.

The first sensing element 10 and the second sensing element 20 are both arranged in a parallel direction across the width of the slot 50. This structure is convenient for observing the state of the silicon wafer, so as to monitor the silicon wafer synchronously.

Specifically, the first sensing element 10 and the second sensing element 20 can be set side by side or staggered up and down, but the spacing distance is not too far or too close, preferably, the adjacent distance is not more than 50 mm. Because it is too far away to reflect the monitoring results of the same silicon wafer, it is worried that abnormal problems cannot be monitored. Too tight for maintenance or installation, or source interference with each other.

In order to facilitate the first sensing element 10 and the second sensing element 20 to monitor and identify the stability, the monitoring system also comprises a mounting plate 30 for fixing the first sensing element 10 and the second sensing element 20 and a crossbar 40 for fixing the mounting plate 30. Both ends of the crossbar 40 are respectively fixed on two sides of the slot 50.

As shown in FIGS. 2 and 4, the mounting plate 30 is a rectangular structure, is arranged along the length direction of the crossbar 40, and is located in the middle of the crossbar 40.

The first sensing element 10 and the second sensing element 20 are both configured at an upper section portion of the mounting plate 30 and above the crossbar 40. This position is more conducive to the first sensing element 10 and the second sensing element 20 tilting the beam towards the direction of the sorting wheel 60, and allows the first sensing element 10 and the second sensing element 20 to have a wider angle for adjustment. The first sensing element 10 and the second sensing element 20 are both opposite optical fiber sensing elements, that is, the transmitter transmitting the optical fiber bundle is fixed on the mounting plate 30, and the receiver for receiving the optical fiber bundle is set at the middle gap of the sorting wheel 60. When there is no silicon wafer on the sorting wheel 60, the transmitter and receiver of the optical fiber sensing element of the first sensing element 10 and the second sensing element 20 are set up in the opposite direction, indicating that there is no silicon wafer signal at present. When the silicon wafer is adsorbed by the sorting wheel 60, the optical fiber transmission signal of the first sensing element 10 and the second sensing element 20 is blocked, indicating the presence of silicon wafers, that is, the first sensing element 10 and the second sensing element 20 can detect signals. Based on the travel time of the first sensing element 10 to test the silicon wafer and the thickness of the second sensing element 20 to test the silicon wafer, the corresponding silicon wafers are monitored.

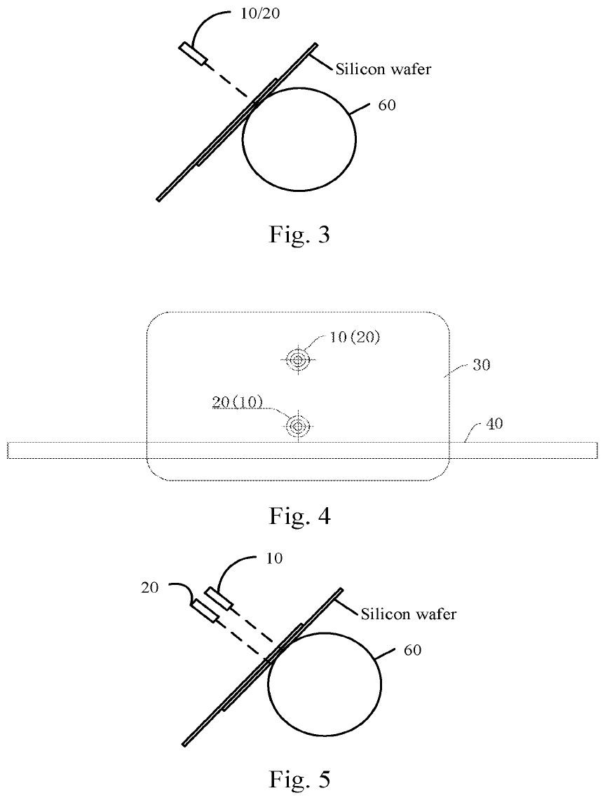

The first sensing element 10 and the second sensing element 20 may be set in the same row of gaps along the length direction of the mounting plate 30, as shown in FIG. 2. That is, they may be set in the same row of gaps along the length direction of the crossbar 40. This structure is convenient for synchronous monitoring of the same silicon wafer. Accordingly, the first sensing element 10 and the second sensing element 20 are arranged in the same row and radiate towards the silicon wafer surface. The specific side monitoring structure is shown in FIG. 3.

When the silicon wafer passes through the emission position of the first sensing element 10, the first sensing element 10 detects a signal, and starts timing from the entrance end of the silicon wafer until its tail passes through the monitoring point of the first sensing element 10, that is, the first sensing element 10 does not receive the signal. Accordingly, the travel time of the silicon wafer continuously moving along its length direction is obtained. After receiving the information transmitted by the first sensing element 10, the system controller compares the travel time with the standard time for a standard single silicon wafer to step along its length, and then determines whether the travel time of the silicon wafer is greater than the standard time. Since the traveling speed of the same silicon wafer is constant, the controller measures the ratio of the distance of the silicon wafer along its length to the measured speed, which is the traveling time of a single silicon wafer. When the travel time of the silicon wafer is greater than the standard time, it indicates that the length of the silicon wafer is greater than its standard length, indicating that adjacent silicon wafers are interconnected, and the silicon wafer is an abnormal silicon wafer. When there is a gap between adjacent silicon wafers, the first sensing element 10 resets again to prepare for monitoring and timing the next group of silicon wafers.

When the travel time of the silicon wafer is within the standard time range, it means that the silicon wafers are not connected. At this time, there are two situations for a silicon wafer. One is that the travel time of a single silicon wafer must be consistent with the standard time. The other is that the travel time of the completely-laminated silicon wafers along its length direction. Then, it is necessary to further determine whether the silicon wafer is an abnormal silicon wafer by the thickness of the silicon wafer measured by the second sensing element 20. It is also determined whether the travel thickness of the silicon wafer measured by the second sensing element 20 is within its standard thickness range.

When the silicon wafer passes the emission position of the second sensing element 20, the second sensing element 20 detects a signal, and starts to monitor the thickness of the silicon wafer from the entrance end of the silicon wafer until its tail passes the monitoring point of the second sensing element 20, and the monitoring signal of the second sensing element 20 is disconnected, so as to obtain the range value of the travel thickness of the silicon wafer continuously moving along its length direction. After receiving the thickness monitoring information transmitted by the second sensing element 20, the system controller can determine whether the thickness range of the silicon wafer is greater than the standard thickness range by comparing the thickness of the line with the standard thickness of a standard single silicon wafer along its length. The thickness value of the silicon wafer monitored by the second sensing element 20 is the thickness value of the unfolded surface after overturning and separation, and it can be seen that the thickness of the silicon wafer obtained is its average value. For either continuous silicon wafers or laminated silicon wafers, the average thickness is greater than the standard thickness of the silicon wafer. For a single silicon wafer, the average value of its thickness measured must fall within the standard thickness range. It can be seen that if the measured average thickness of the silicon wafer is within the range of the standard thickness, it means that the silicon wafer is a normal silicon wafer. If the measured average thickness of the silicon wafer is greater than the range of the standard thickness, the silicon wafer is an abnormal silicon wafer. When there is a gap between adjacent silicon wafers, the second sensing element 20 resets again to prepare for monitoring and timing the next group of silicon wafers.

When the monitoring system monitors that the silicon wafer is abnormal through the first sensing element 10 and the second sensing element 20, the controller will automatically notify the sorting wheel in the washer to stop sorting and give an alarm. After hearing the alarm, the staff can take out the abnormal silicon wafer and restart the machine to continue working. At the same time, the controller also informs the step speed of the silicon wafer in the cleaning tank (omitted in the figure) before the sorting wheel 60 that is, the silicon wafer behind the abnormal silicon wafer in the cleaning tank is notified to reduce its step amount, so as to avoid that the subsequent silicon wafer still moves at the original speed, automatically adjust the step speed of the subsequent silicon wafer, and then resume the original step speed for sorting after the silicon wafer is normally sorted.

The first sensing element 10 and the second sensing element 20 can also be set up in the same column at intervals perpendicular to the length direction of the mounting plate 30. At this time, the first sensing element 10 and the second sensing element 20 are located on the center line position in the middle of the mounting plate 30, as shown in FIG. 4. This structure can also monitor the same silicon wafer. Accordingly, the first sensing element 10 and the second sensing element 20 are arranged in the same column and radiate towards the silicon wafer surface. The specific side monitoring structure is shown in FIG. 5.

The mounting plate 30 and the crossbar 40, the first sensing element 10 and the mounting plate 30, and the second sensing element 20 and the mounting plate 30 are all detachable. It is convenient for installation and commissioning, maintenance and replacement.

The width of the mounting plate 30 shall not be greater than ⅕ of the length of the crossbar 40, so as to reduce the weight of the entire monitoring system and reduce the overall burden.

The monitoring system also comprises a controller electrically connected with the first sensing element 10 and the second sensing element 20 (omitted in the figure). The controller is placed outside the slot 50 to respond to the signals input by the first sensing element 10 and the second sensing element 20 and determine whether to stop the step operation of the silicon wafer.

In operation, the first sensing element 10 and the second sensing element 20 radiate towards the surface of the silicon wafer respectively. The first sensing element 10 measures the transmission time of the measurement of two adjacent silicon wafers. Once the time is greater than the transmission time of a single silicon wafer, it indicates that the group of silicon wafers is interconnected with the next group of silicon wafers. The first sensing element 10 transmits the monitored information to the external controller via electrical signals, and the controller determines that the group of silicon wafers is abnormal. Then, the shutdown signal is directly transmitted to the slicer to stop sorting and give an alarm. The staff can take out the abnormal silicon wafer after hearing the alarm, and then restart the machine to continue working.

The second sensing element 20 measures the thickness of each group of silicon wafers. Once the measured silicon wafer thickness is greater than the thickness range of a single silicon wafer, it indicates that this group of silicon wafers overlaps with the next group of silicon wafers. The second sensing element 20 transmits the monitored information included in an electrical signal to the external controller. The controller determines that this group of silicon wafers is abnormal, and then directly transmits the shutdown signal to the slicer to stop sorting and give an alarm. The staff can take out the abnormal silicon wafer after hearing the alarm, and then restart the machine to continue working.

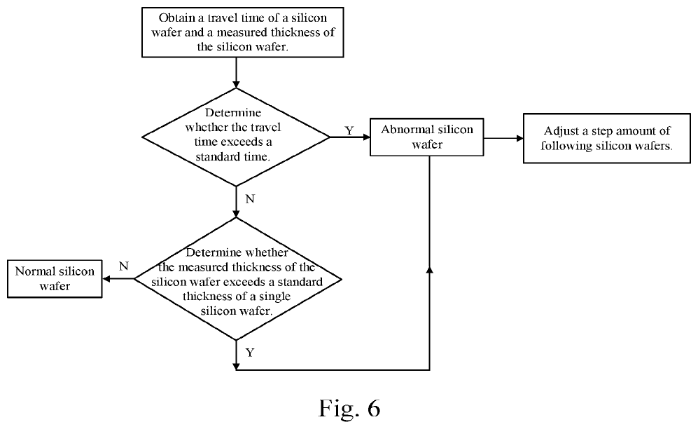

A monitoring method for moving and stepping silicon wafers, which adopts the monitoring system mentioned above, as shown in FIG. 6.

The silicon wafers are absorbed and turned over one by one by the sorting wheel 60 from the vertically placed cleaning tank to be divided into horizontal moving ways. During the silicon wafer stepping process, the first sensing element 10 monitors the starting time of each silicon wafer passing through the same monitored position to obtain the travel time of the silicon wafer. At the same time, the thickness range at the same monitored position where the silicon wafer passes through is monitored by the second sensing element 20 to obtain the thickness of the silicon wafer. The monitored position of the first sensing element 10 for silicon wafer irradiation and the monitored position of the second sensing element 20 for silicon wafer irradiation can be set at the same horizontal line along the width of the silicon wafer or at the same vertical line along the length of the silicon wafer, but both can monitor the travel time or travel thickness of the silicon wafer.

Then, based on the comparison of the travel time and travel thickness of the silicon wafer obtained with the standard time and standard thickness of a single silicon wafer step, it is determined whether the silicon wafer is an abnormal silicon wafer.

The first sensing element 10 and the second sensing element 20 are placed at the same time to monitor the silicon wafer when the silicon wafer is turned over from the vertical position. The detection position is shown in FIG. 3 or 5. The detection position is the position where the silicon wafer is inclined to be closely adsorbed by the sorting wheel 60, and the first sensing element 10 and the second sensing element 20 are vertically irradiated towards the surface of the silicon wafer, so as to obtain accurate monitoring of the travel time and travel thickness of the silicon wafer. No matter how the positions of the first sensing element 10 and the second sensing element 20 are arranged, the travel time and travel thickness of the same silicon wafer can be monitored during the silicon wafer stepping process.

When the silicon wafer passes through the emission position of the first sensing element 10, the first sensing element 10 detects a signal, and starts timing from the entrance end of the silicon wafer until its tail passes through the monitoring point of the first sensing element 10, that is, the first sensing element 10 does not receive the signal. Accordingly, the travel time of the silicon wafer continuously moving along its length direction is obtained. After receiving the information transmitted by the first sensing element 10, the system controller compares the travel time with the standard time for a standard single silicon wafer to step along its length, and then determines whether the travel time of the silicon wafer is greater than the standard time. Since the traveling speed of the same silicon wafer is constant, the controller measures the ratio of the distance of the silicon wafer along its length to the measured speed, which is the traveling time of a single silicon wafer. When the travel time of the silicon wafer is greater than the standard time, it indicates that the length of the silicon wafer is greater than its standard length, indicating that adjacent silicon wafers are interconnected, and the silicon wafer is an abnormal silicon wafer. When there is a gap between adjacent silicon wafers, the first sensing element 10 resets again to prepare for monitoring and timing the next group of silicon wafers.

When the travel time of the silicon wafer is within the standard time range, it means that the silicon wafers are not connected. At this time, there are two situations for a silicon wafer. One is that the travel time of a single silicon wafer must be consistent with the standard time. The other is that the travel time of the completely-laminated silicon wafers along its length direction is also consistent with the standard time. Then, it is necessary to further determine whether the silicon wafer is an abnormal lamination by the thickness of the silicon wafer measured by the second sensing element 20, that is, whether the travel thickness of the silicon wafer measured by the second sensing element 20 is within its standard thickness range.

When the travel time of the silicon wafer is within the standard time range, it means that the silicon wafers are not connected. At this time, there are two situations for a silicon wafer. One is that the travel time of a single silicon wafer must be consistent with the standard time. The other is that the travel time of the completely-laminated silicon wafers along its length direction. Then, it is necessary to further determine whether the silicon wafer is an abnormal silicon wafer by the thickness of the silicon wafer measured by the second sensing element 20. It is also determined whether the travel thickness of the silicon wafer measured by the second sensing element 20 is within its standard thickness range.

When the silicon wafer passes the emission position of the second sensing element 20, the second sensing element 20 detects a signal, and starts to monitor the thickness of the silicon wafer from the entrance end of the silicon wafer until its tail passes the monitoring point of the second sensing element 20, and the monitoring signal of the second sensing element 20 is disconnected, so as to obtain the range value of the travel thickness of the silicon wafer continuously moving along its length direction. After receiving the thickness monitoring information transmitted by the second sensing element 20, the system controller can determine whether the thickness range of the silicon wafer is greater than the standard thickness range by comparing the thickness of the line with the standard thickness of a standard single silicon wafer along its length. The thickness value of the silicon wafer monitored by the second sensing element 20 is the thickness value of the unfolded surface after overturning and separation, and it can be seen that the thickness of the silicon wafer obtained is its average value. For either continuous silicon wafers or laminated silicon wafers, the average thickness is greater than the standard thickness of the silicon wafer. For a single silicon wafer, the average value of its thickness measured must fall within the standard thickness range. It can be seen that if the measured average thickness of the silicon wafer is within the range of the standard thickness, it means that the silicon wafer is a normal silicon wafer. If the measured average thickness of the silicon wafer is greater than the range of the standard thickness, the silicon wafer is an abnormal silicon wafer. When there is a gap between adjacent silicon wafers, the second sensing element 20 resets again to prepare for monitoring and timing the next group of silicon wafers.

When the monitoring system monitors that the silicon wafer is abnormal through the first sensing element 10 and the second sensing element 20, the controller will automatically notify the sorting wheel in the washer to stop sorting and give an alarm. After hearing the alarm, the staff can take out the abnormal silicon wafer and restart the machine to continue working. At the same time, the controller also informs the step speed of the silicon wafer in the cleaning tank (omitted in the figure) before the sorting wheel 60 that is, the silicon wafer behind the abnormal silicon wafer in the cleaning tank is notified to reduce its step amount, so as to avoid that the subsequent silicon wafer still moves at the original speed, automatically adjust the step speed of the subsequent silicon wafer, and then resume the original step speed for sorting after the silicon wafer is normally sorted.

The monitoring system for moving and stepping silicon wafers designed by the present disclosure is installed in the narrow space between the cleaning tank and the sorting tank, has simple structure and is easy to control, is capable of quickly and accurately monitoring the silicon wafer turnover, and accurately determining whether there is a continuous or laminated silicon wafers during the silicon wafer turnover process.

The present disclosure is also directed to the monitoring method for moving and stepping silicon wafers, which adopts the monitoring system. Based on the comparison of the travel time and travel thickness of silicon wafers with the standard time and standard thickness, it can determine whether the silicon wafers are continuous silicon wafers or laminated silicon wafers, so as to find abnormal silicon wafers. The detection process is simple, easy to control, and accurate. It can also automatically adjust the step size of subsequent silicon wafers in the migration process.

The principles and implementations of the present disclosure are described herein by using specific examples, and the descriptions of the above embodiments are only used to help to understand the technical solutions and core ideas of the present disclosure. One of ordinary skill in the art should understand that the technical solutions described in the foregoing embodiments can be modified, or some of the technical features can be replaced equivalently. The modification or replacement does not make the essence of the corresponding technical solutions depart from the scope of the technical solutions of the embodiments of the present disclosure.

What is claimed is:

1. A system for monitoring moving and stepping silicon wafers, comprising:
a first sensing element, configured to monitor whether a gap between adjacent silicon wafers exists; and
a second sensing element, configured to monitor whether two silicon wafers are laminated;
wherein the first sensing element and the second sensing element are both disposed in a slot where the silicon wafers are turned over, and the first sensing element and the second sensing element are both suspended on a front side of a sorting wheel in the slot and obliquely arranged towards one side of the sorting wheel.

2. The system as claimed in claim 1, wherein the first sensing element and the second sensing element are both disposed in an end of the slot near the sorting wheel.

3. The system as claimed in claim 1, wherein the first sensing element and the second sensing element are disposed in a direction and orientated in the same direction across a width of the slot;
the first sensing element and the second sensing element are arranged side-by-side at intervals or positioned in offset arrangement along a vertical direction.

4. The system as claimed in claim 1, further comprising a mounting plate configured to fix the first sensing element and the second sensing element and a crossbar used for fixing the mounting plate, wherein two ends of the crossbar are respectively fixed on two side walls of the slot;
the mounting plate is arranged along a length direction of the crossbar and located in the middle of the crossbar;
the first sensing element and the second sensing element are both configured at an upper section portion of the mounting plate and located above the crossbar.

5. The system as claimed in claim 4, wherein the mounting plate and the crossbar are detachably connected; the first sensing element, the second sensing element and the mounting plate are detachably connected;
a width of the mounting plate is not greater than one fifth of a length of the crossbar.

6. The system as claimed in claim 1, further comprising a controller electrically connected to the first sensing element and the second sensing element, wherein the controller is disposed at an outer side of the slot.

7. A method for monitoring moving and stepping silicon wafers, performed with a monitoring system comprising a first sensing element configured to monitor whether a gap between adjacent silicon wafers exists, and a second sensing element configured to monitor whether two silicon wafers are laminated, wherein the first sensing element and the second sensing element are both disposed in a slot where the silicon wafers are turned over, and the first sensing element and the second sensing element are both suspended on a front side of a sorting wheel in the slot and obliquely arranged towards one side of the sorting wheel;
wherein the method comprises:
monitoring a starting time of each of the silicon wafers passing through a measured position to obtain a travel time of the silicon wafer during a time period of silicon wafer stepping;
measuring a thickness of the silicon wafer at the measured position to obtain a measured thickness of the silicon wafer;
determining whether the silicon wafer is an abnormal silicon wafer based on a comparison of the travel time with a standard time and a comparison of the measured thickness of the silicon wafer with a standard thickness of a single silicon wafer.

8. The method as claimed in claim 7, further comprising:
determining that the silicon wafer is an abnormal silicon wafer when the travel time exceeds the standard time.

9. The method as claimed in claim 7, further comprising:
determining that the silicon wafer is a normal silicon wafer when the travel time is within the standard time and the measured thickness of the silicon wafer is within the standard thickness of the single silicon wafer; and
determining that the silicon wafer is an abnormal silicon wafer when the travel time is within the standard time and the measured thickness of the silicon wafer is not within the standard thickness of the single silicon wafer.

10. The method as claimed in claim 9, further comprising:
adjusting a step amount of following silicon wafers after the abnormal silicon wafer is determined.
